(19) United States
(12) Patent Application Publication
(10) Pub. No.: US 2006/0057478 A1
(43) Pub. Date: Mar. 16, 2006

(54) Panel for display device and manufacturing method thereof

(75) Inventors: Seong-Gyu Kwon, Suwon-si (KR); Yoon-Ho Kang, Yongin-si (KR); Jang-Sub Kim, Suwon-si (KR); Byoung-Joo Kim, Anyang-si (KR)

Correspondence Address: MCGUIREWOODS, LLP, 1750 TYSONS BLVD, SUITE 1800, MCLEAN, VA, 22102, US

(73) Assignee: Samsung Electronics Co., Ltd.

(21) Appl. No.: 11/217,398

(22) Filed: Sep. 2, 2005

(30) Foreign Application Priority Data
Sep. 15, 2004 (KR) 10-2004-0073823
Nov. 12, 2004 (KR) 10-2004-0092606

(51) Int. Cl. G03F 1/00

(52) U.S. Cl. 430/7

(57) ABSTRACT

A panel for a display device is provided, which includes a substrate, a sidewall member formed on the substrate and having a plurality of openings, a plurality of color filters formed into the openings and representing a color by incident light, and at least one inspection pattern inspecting a misalignment of the color filters.

### CROSS REFERENCE TO RELATED APPLICATIONS

This application claims priority to and the benefit of Korean Patent Application No. 10-2004-0073823, filed on Sep. 15, 2004, and Korean Patent Application No. 10-2004-0092606, filed on Nov. 12, 2004, which are hereby incorporated by reference for all purposes as if fully set forth herein.

### BACKGROUND OF THE INVENTION

1. Field of the Invention

The present invention relates to a panel for a display device and a manufacturing method thereof.

2. Description of Related Art

Flat panel displays, such as organic electroluminescence displays (“OLEDs”), plasma display panels (“PDPs”), and liquid crystal displays (“LCDs”), are gaining in popularity.

A PDP device displays an image using plasma generated by a gas-discharge. An OLED device displays an image by applying an electric field to specific light-emitting or high molecules. An LCD device displays an image by applying an electric field to a liquid crystal layer disposed between two panels and regulating the strength of the electric field to adjust the transmittance of light passing through the liquid crystal layer.

Among the flat panel displays described above, the LCD and the OLED displays each include a plurality of pixels having switching elements, display signal lines having gate lines and data lines, and color filters representing colors. The OLED may also include an organic light emitting layer instead of the color filters.

A variety of processes, such as inkjet printing, have recently been developed for forming the color filters and the organic light emitting layer, which are replacing photolithography.

The inkjet printing includes depositing a light blocking member, such as a black matrix, on an insulating substrate, forming openings corresponding to pixels by exposing and developing the light blocking member, and depositing ink for the color filters into the openings. In the inkjet printing process, since the coating, the exposing, the developing, etc., are not necessary, manufacturing cost may decrease and the manufacturing process may be simplified by eliminating the same.

The ink for the color filters is a liquid phase composition that includes pigments, solvents, and dispersants. It is difficult to deposit the ink into fine or small openings in a desired amount. It is difficult to compute a distance from a desired deposit point to deposit the ink. When deposited, the ink freely spreads within the openings, making it difficult to determine misalignment. Accordingly, when the ink is not precisely deposited, the ink spreads between adjacent color filters, which decreases the image quality of the display device.

### SUMMARY OF THE INVENTION

A motivation of the present invention is to solve the problems of conventional techniques.

Additional features of the invention will be set forth in the description which follows, and in part will be apparent from the description, or may be learned by practice of the invention.

The present invention discloses a panel for a display device, including a substrate, a sidewall member formed on the substrate and having a plurality of openings, a plurality of color filters formed in the openings, and at least one inspection pattern for inspecting a misalignment of the color filters.

The present invention also discloses a method of manufacturing a panel for a display device, including depositing ink into an inspection pattern, inspecting a position of the deposited ink in the inspection pattern, adjusting a position of a substrate or a head of an inkjet printing device to align a center point of the deposited ink with a center point of the inspection pattern, and depositing ink into an opening.

The present invention also discloses a panel for a display device, including a substrate, a sidewall member provided on the substrate and including a plurality of openings, a plurality of organic light emitters provided in the openings and representing a color, respectively, and an inspection pattern for inspecting a misalignment of the organic light emitters.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

FIG. 1 is a top view of a panel according to an embodiment of the invention.

FIG. 2 is a top view of an inspection pattern formed on a panel according to an embodiment of the invention.

FIG. 3 is a top view of an inspection pattern onto which a drop of ink is deposited according to an embodiment of the invention.

FIG. 4 is a top view of color filters and alignment patterns formed on a panel according to another embodiment of the invention.

FIG. 5 is a perspective view of an inkjet printing device used during manufacturing of a panel according to an embodiment of the invention.

FIG. 6 is a top view of a head of the inkjet printing device according to an embodiment of the invention.

FIG. 7 illustrates procedures for aligning a head using an alignment pattern before forming the color filters during manufacturing of the panel shown in FIG. 4.

FIGS. 8A, 8B, 8C, and 8D each illustrate examples of misalign shapes occurring in an alignment pattern during manufacturing of the panel shown in FIG. 4.

FIG. 9 is a sectional view of an LCD having a panel according to an embodiment of the invention.

FIG. 10 is a layout view of a TFT array panel of an OLED according to an embodiment of the invention.

FIG. 11 and FIG. 12 are sectional views of the TFT array panel shown in FIG. 10 taken along the line XI-XI′.

### DESCRIPTION OF THE ILLUSTRATED EMBODIMENTS

The present invention is described more fully below with reference to the accompanying drawings, in which preferred embodiments of the inventions invention are shown. This invention may, however, be embodied in many different forms and should not be construed as limited to the embodiments set forth herein.

In the drawings, the thickness of layers and regions are exaggerated for clarity. Like numerals refer to like elements throughout. It is understood that when an element such as a layer, film, region, substrate, or panel is referred to as being “on” another element, that element may be directly on the other element or intervening elements may be present. However, when an element is referred to as being “directly on” another element, no intervening elements are present.

Panels for a display device and manufacturing methods thereof according to embodiments of the invention are described below with reference to the drawings.

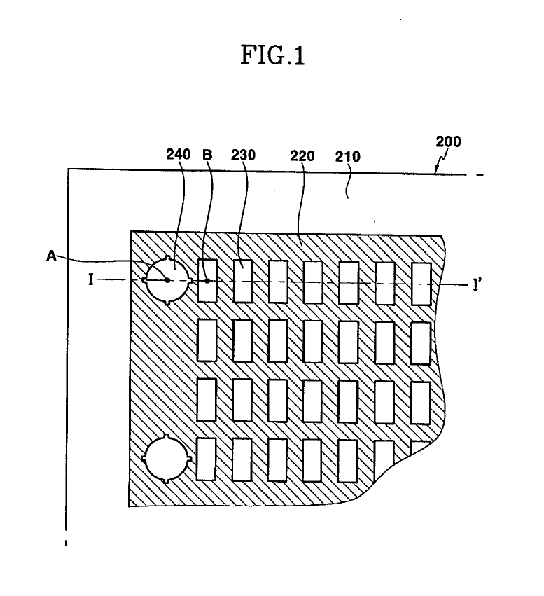

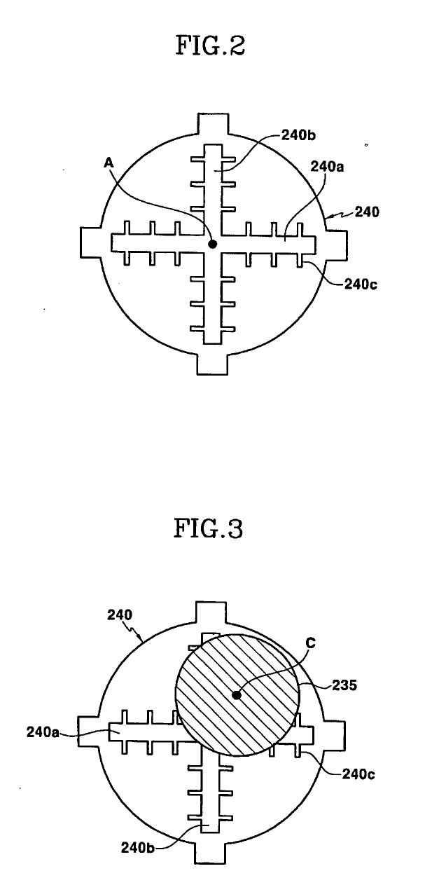

FIG. 1 is a top view of a panel according to an embodiment of the invention. FIG. 2 is a top view of an inspection (alignment) pattern formed on a panel according to an embodiment of the invention. FIG. 3 is a top view of an inspection (alignment) pattern onto which a drop of ink is deposited according to an embodiment of the invention.

Referring to FIG. 1, a panel for a display device includes an insulating substrate 210, a light blocking member 220 provided, e.g., formed on the insulating substrate 210 and having openings corresponding to pixels, and a plurality of color filters 230 formed into the openings of the light blocking member 220. For example, the color filters 230 may represent one of the three primary colors comprising red, green, and blue. The light blocking member 220 prevents or significantly reduces light leakage between neighboring pixels to improve luminance and also functions as side walls to house or contain ink for color filters when the panel is manufactured.

The light blocking member 220 may be formed by forming a metal film, such as Cr, on the substrate 210 using a vacuum deposition process, coating a photoresist resin thereon, pattering the photoresist resin using a photolithography process, and etching the Cr by using the photoresist resin as a mask. Alternatively, the light blocking member 220 may be formed by depositing a high molecular weight resin liquid onto the substrate 210 and spin-coating, or by another method.

On an area that is outside or peripheral to the area where the color filters 230 are disposed, e.g., on the edge portion of the light blocking member 220, inspection (or alignment) patterns 240 are formed for precisely inspecting an ink-deposited position when manufacturing the color filters 230. In FIG. 1, the inspection patterns 240 are shown as openings having a substantially circular-like shape, however, the inspection patterns may be formed of various shapes. The respective inspection patterns 240 may have projections projecting or extending in a substantially horizontal direction and/or a substantially vertical direction.

A center point A of the inspection pattern 240 is provided along the same line as a center point B of the color filter 230. The center point A of the inspection patterns 240 and all the center points B of the color filters 230 disposed along the same row are disposed along an I-I′ line, as shown in FIG. 1. If the respective center points A and B are not disposed along the I-I′ line, then the ink for color filters 230 may not be precisely deposited, which decreases reliability of an alignment inspection that is performed using the inspection pattern 240.

At least one inspection pattern 240 may be provided along the edge portion of the light blocking member 220, and may be provided on an area that is outside or peripheral to the light blocking member 220. The space between ink supply nozzles (not shown) for depositing the ink, and the space between the color filters 230 may be determined by a calculation. Thus, when precisely detecting an ink-deposited position by the one inspection pattern 240 and defining the positions of the ink supply nozzles based on the detected result, the ink may be deposited into openings of the light blacking layer 220. There may be more than one inspection pattern 240 which would improve the accuracy of the inspection. In addition, an inspection pattern 240 may be provided for every color filter row or column having the same color.

The inspection patterns 240 may be formed in various ways in accordance with an ink supply device or an ink depositing manner.

The inner size of the respective inspection patterns 240 may vary; however, the size is preferably larger than the size of the ink spreading area.

When the light blocking member 220 includes an organic high molecular compound, the inspection patterns 240 may be formed by only exposing and developing a positive or negative type of the light blocking member 220. However, when the light blocking member 220 is made of an inorganic material, after depositing a separate photoresist film, the inspection patterns 240 may be formed on the light blocking member 220 by exposing, developing, and etching.

As shown in FIG. 2, each inspection pattern 240 may include a first alignment line 240a formed in an ink injection direction, and a second alignment line 240b orthogonal to the first alignment line 240a at the center point A. For example, the first alignment line 240a and the second alignment line 240b may intersect and form a t-like shape. Projections of the inspection pattern 240 are disposed along each of the first and second alignment lines 240a and 240b. The projections operate to guide top and bottom and right and left position relations so that the ink deposit state may be more easily determined. The alignment lines 240a and 240b include a plurality of alignment divisions 240c. An ink deposited position is calculated according to the alignment lines 240a and 240b in order to inspect or locate a misalignment of deposited ink. Accordingly, fine position adjustment of the ink supply nozzles (not shown) is possible. It is understood that the first and second alignment lines 240a and 240b may be formed of various shapes.

For example, the first and second alignment lines 240a and 240b may be patterned simultaneously with the inspection patterns 240 or they may be patterned after the inspection patterns 240 are formed. To simplify, the manufacturing process, the alignment lines 240a and 240b and the inspection patterns 240 are preferably formed simultaneously.

The first and second alignment lines 240a and 240b may have a relievo pattern or an intaglio pattern. The alignment lines 240a and 240b may have a surface height that is equal to a surface height of the light blocking member 220 to prevent the free flowing of the deposited ink.

A method of forming the color filters according to an embodiment of the invention is described below with reference to FIG. 3.

A head attached with the ink supply nozzles of an inkjet printing device is aligned on the substrate 210 having the light blocking member 220 and a plurality of inspection patterns 240. The inkjet printing device deposits a drop of ink 235 into each inspection pattern 240 via the ink supply nozzle.

The inkjet printing device then detects a position of the deposits ink 235 with respect to the inspection pattern 130, adjusts the head or the ink supply nozzle position to align a center point C of the deposited ink 235 with a center point A of the inspection pattern 240 to define a reference ink-deposited position. The inkjet printing device deposits ink 235 into openings of the light blocking member 220 that are formed along the same elongated line with the inspection pattern 240 according to the reference ink-deposited position. The openings of the light blocking member (referring to FIG. 1) 220 are formed by the exposing and the developing operations to receive the deposited ink 235. The deposited ink 235 becomes a color filter after a curing operation.

The inkjet printing device may simultaneously deposit ink into all the inspection patterns 240, or may deposit ink into inspection patterns corresponding to the same color at the same time. One inspection pattern 240 may be formed for every color.

The number of the inspection patterns 240 and an arrangement manner thereof may vary according to the arrangement of the color filters 230.

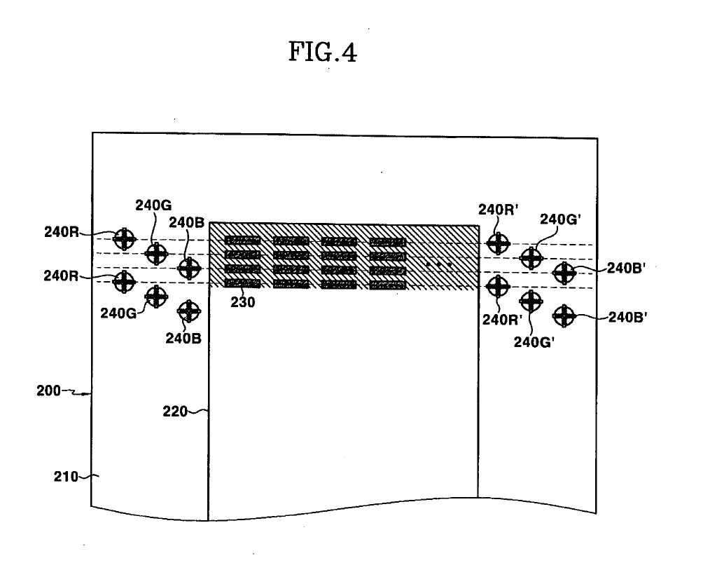

Color filters and inspection patterns according to an embodiment of the invention are described below with reference to FIG. 4.

FIG. 4 is a top view of color filters and alignment patterns formed on a panel according to an embodiment of the invention.

Referring to the embodiment shown in FIG. 4, the configuration of a panel 200 for a display device is substantially the same as that of the display panel shown in FIGS. 1 to 3. The panel 200 includes a light blocking member 220 having a plurality of openings corresponding to pixels and formed on an insulating substrate 210, a plurality of color filters 230 formed on the openings, and a plurality of inspection patterns 240R, 240G, 240B, 240R′, 240G′, and 240B′ formed on portions of the substrate 210 that are outside or peripheral to the color filters 230.

Unlike embodiments shown in FIGS. 1, 2, and 3, the color filters 230, e.g., for the three primary colors of red, green, and blue, are disposed, preferably sequentially, on the display panel 200 in a substantially vertical direction. As shown in FIG. 4, the inspection patterns 240R, 240G, 240B, 240R′, 240G′, and 240B′ are disposed on an outer area of the light blocking member 220 that is outside of the color filters 230 and near the periphery of the substrate 210.

The inspection patterns 240R, 240G, 240B, 240R′, 240G′, and 240B′ are disposed on both outer sides of the substrate 210 with respect to the light blocking member 220 near an elongated line of openings arranged on the same line in a substantially horizontal direction. A substantially horizontal center line of the inspection patterns 240R, 240G, 240B, 240R′, 240G′, and 240B′ is the same as that of the color filters 230. The respective inspection patterns 240R, 240G, 240B, 240R′, 240G′, and 240B′ may be formed for one color filter row and may include inspection patterns 240R and 240R′ for red color filters, inspection patterns 240G and 240G′ for green color filters, and inspection patterns 240B and 240B′ for blue color filters. Since the respective inspection patterns 240R, 240G, 240B, 240R′, 240G′, and 240B′ are larger than the color filters 230, for example by at least approximately 1.5 times, the respective inspection patterns 240R, 240G, 240B, 240R′, 240G′, and 240B′ are in turn disposed on each other, and center lines of the inspection patterns 240R, 240G, 240B, 240R′, 240G′, and 240B′ for the same color are the same for each other in a substantially vertical direction.

The shape of the color filters 230 and the shape or number of the inspection patterns 240R, 240G, 240B, 240R′, 240G′, and 240B′ may vary. The inspection patterns 240R, 240G, 240B, 240R′, 240G′, and 240B′ may also be variously arranged.

The inspection patterns 240R, 240G, 240B, 240R′, 240G′, and 240B′ may be formed with the light blocking member 220. The inspection patterns 240R, 240G, 240B, 240R′, 240G′, and 240B′ may be formed by drawing or by patterning another thin film before forming the light blocking member 220.

The display panel may be a color filter panel that only has the color filters. The light blocking member 220 prevents light leakage between neighboring pixels to improve luminance. The display panel may be to be a thin film transistor array panel or a common electrode panel when the display device is an LCD or an OLED. The light blocking member 220 functions as side walls for housing ink for color filters when manufacturing the panel.

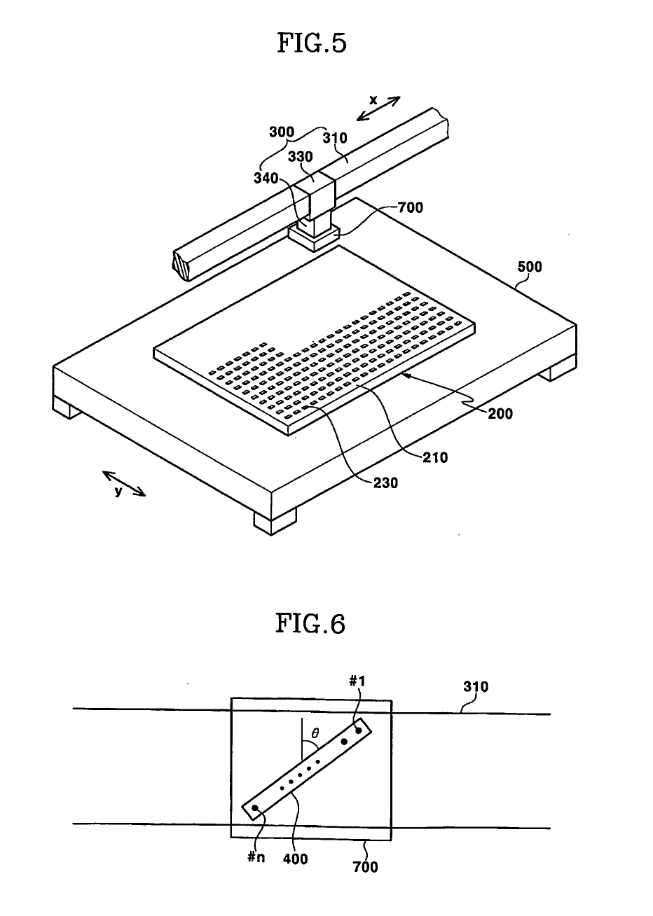

An inkjet printing apparatus for forming the color filters according to another embodiment of the invention is described below with reference to FIG. 5 and FIG. 6.

FIG. 5 is a perspective view of an inkjet printing device for manufacturing a panel according to an embodiment of the invention. FIG. 6 is a top view of a head of the inkjet printing device according to an embodiment of the invention.

As shown in FIG. 5 and FIG. 6, an inkjet printing device includes a stage 500 on which an insulating substrate of a display panel 200 is provided, a head unit 700, and a transporting unit 300 that transports the head unit 700 to a predetermined position.

The head unit 700 includes a head 400 and at least one ink supply nozzle attached or connected with the head 400. The head unit 700 may deposit ink 235 for color filters through the ink supply nozzles #1 through #n on the substrate 210.

For forming color filters 230 on the substrate 210 arranged on the stage 500, the inkjet printing device deposits ink 235 through the nozzles #1 to #n as it transports the head unit 700 in an X direction using the transporting unit 300. Thus, the ink 235 is deposited on the substrate 210 to form the color filters 230 thereon. The size of the substrate 210 may be increased, but the number of the nozzles #1 to #n and the size of the head 400 are defined or set to a predetermined amount. Thus, since all the color filters 230 are not formed by a single scanning, the head unit 700 repeatedly transports the entire substrate 210 to form all of the color filters 230.

The transporting unit 300 includes a supporting unit 310 to keep the head unit 700 space at a predetermined distance from the substrate 210, a transporting portion 330 for transporting in X and Y directions, and an elevating unit 340 for elevating the head unit 700.

The above-described head 400 of the head unit 700 supports the ink supply nozzles #1 through #n and may include three heads for red, green, and blue colors, respectively. The head 400 may have a long bar-like shape however it is not limited to such shape. The nozzles #1 through #n are provided on the entire surface of the head 400.

For example, when there are three heads, each head is spaced by an equal distance and are parallel with each other. A plurality of heads may be separately arranged by the horizontal transporting, the vertical transporting, and the rotating transporting.

The head 400 is inclined at a predetermined angle θ with respect to the Y direction. For example, since a nozzle pitch (a distance between adjacent nozzles) is different from a pixel pitch (a distance between adjacent pixels to be printed), by rotating the head 400 at the predetermined angle θ, an interval between adjacent ink deposits through the nozzles #1 through #n and the pixel pitch may coincide.

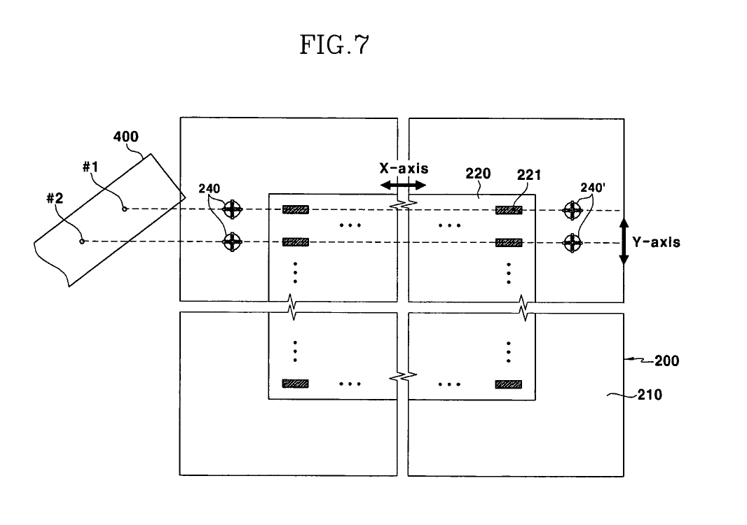

A method of forming the color filters using the inkjet printing device according to an embodiment of the invention is described below with reference to FIG. 7. The forming method of one color filter is described below, however it is understood that such method may be applied to other color filters.

FIG. 7 illustrates a procedure for aligning a head using an alignment pattern before forming the color filters when manufacturing the panel shown in FIG. 4.

As shown in FIG. 7, a panel 200 is arranged and disposed on the stage 500. The panel 200 includes a light block layer 220 having a plurality of openings 221 positioned corresponding with pixels and inspection patterns 240 and 240′. An inkjet printing device transports the head unit 700 using the transporting unit 300 according to position information of the inspection pattern 240 already stored therein, and deposits a drop of ink 235 into the inspection patterns 240. It is understood that the above described procedure may be carried out for one color filter or may be simultaneously carried out for multiple filters, e.g., two or three.

The inkjet printing device detects a position of a center point C of the deposited ink 235 and accordingly adjusts a position of the head 700 or the first ink supply nozzle #1 to align the center point C with a center point A of the inspection pattern 240. The inkjet printing device preferably adjusts the nozzle #1. The above described aligning is repeated for the remaining inspection patterns 240 and 240′, which are provided on opposite sides of the stage with respect to the light blocking member 220, and the remaining nozzles #2 through #n. In addition, for inspecting misalignment between the nozzles #1 through #n and the substrate 210, two inspection patterns 240 and 240′ or more may be selected for inspecting misalignment between the nozzles #1 through #n. The inspection patterns 240 and 240′ selected are preferably located on opposite sides of the stage, which is A for distance.

The inkjet printing device then adjusts the position of the nozzles #1 through #n or the substrate 210 according to the adjusted position, to deposit ink into the openings 221 while transporting the head unit 400.

The inkjet printing device may simultaneously deposit ink into a plurality of the inspection patterns 240 to inspect the misalignment. The inkjet printing device may simultaneously deposit ink into inspection patterns corresponding to the same color. For example, one inspection pattern 240 is formed for every color filter row having the same color.

The number of inspection patterns 240 and an arrangement manner may vary depending on the arrangement of the color filters 230.

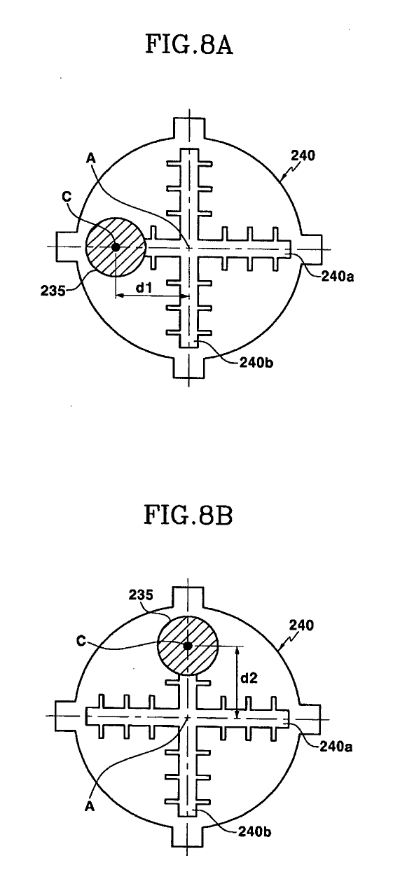

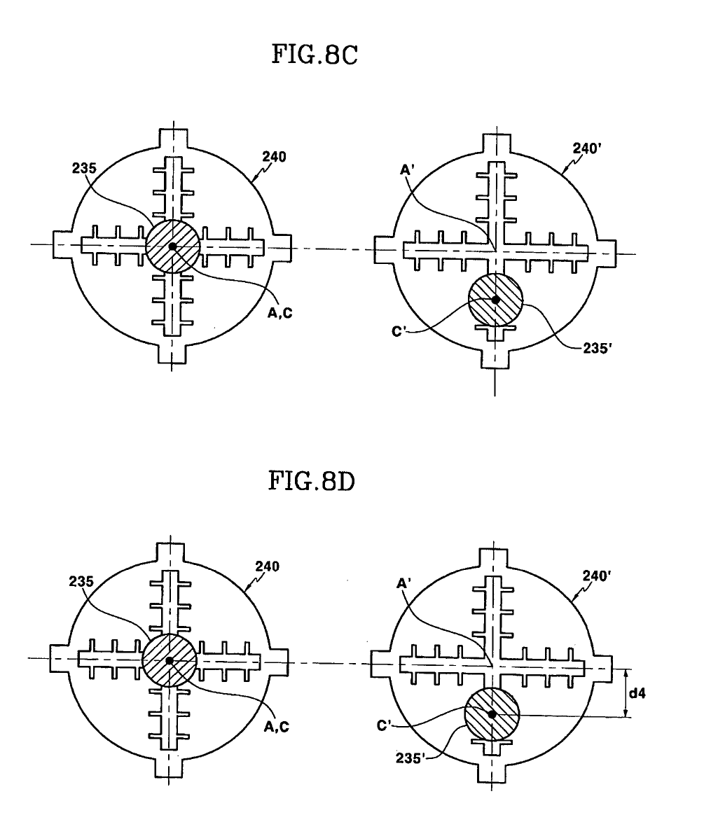

The shape of the misalignments and the changed shapes of the misalignments according to embodiments of the invention are described below with reference to FIGS. 8A, 8B, 8C, and 8D.

FIGS. 8A, 8B, 8C, and 8D illustrate examples of misalignment shapes occurring in an alignment pattern when the panel is manufactured as shown in FIG. 4.

As shown in FIG. 8A, a center point C of the deposited ink 235 is misaligned with respect to a center point A of the inspection pattern 240 by a distance d1 in an X-axis direction. The misalignment may be changed to adjust the initial fixed position of the head 400 by the distance d1.

As shown in FIG. 8B, a center point C of the deposited ink 235 is misaligned with respect to a center point A of the inspection pattern 240 by a distance d2 in a Y-axis direction. The misalignment may be changed to adjust the initial fixed position of the substrate 210 or state 500 by the distance d2.

As shown in the left figure of FIG. 8C, a center point C of the deposited ink 235 coincides with a center point A of the inspection pattern 240. However, as shown in the right figure, when ink 235′ is deposited through another nozzle, such as a second nozzle #2 formed on the head 400, into a second inspection pattern 240′, the center point C′ of the deposited ink 235′ does not coincide with the center point A′ of the inspection pattern 240′. Therefore, because an inclined angle of the head 400 is misaligned, the misalignment is changed to adjust the inclined angle of the head 400.

As shown in the left figure of FIG. 8d, a center point C of the deposited ink 235 coincides with a center point A of the inspection pattern 240. However, as shown in the right figure, a center point C′ of the ink 235′ deposited into another inspection pattern 240′ is misaligned with a center point A′ of the inspection pattern 240′ by a distance d4 in a Y-axis direction. Therefore, because an inclined angle of the substrate 210 or the stage 500 is misaligned, the misalignment is changed to adjust the inclined angle of the substrate 210 or the stage 500.

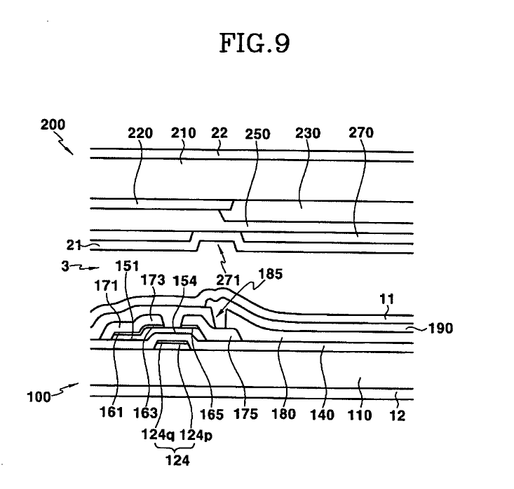

An LCD having a display panel according to an embodiment of the invention is described below with reference to FIG. 9. FIG. 9 is a sectional view of an LCD having a panel according to an embodiment of the invention.

As shown in FIG. 9, an LCD includes a TFT array panel 100, a common electrode panel 200, and an LC layer 3 provided between the panels 100 and 200.

A plurality of gate electrodes 124 are formed on an insulating substrate 110. Each gate electrode 124 is connected with one of a plurality of gate lines (not shown) transmitting gate signals. A gate insulating layer 140 is formed on the gate lines. The semiconductors 151 and 154, which may be made of hydrogenated amorphous silicon (abbreviated to “a-Si”) are formed on the gate insulating layer 140.

A plurality of ohmic contacts 161, 163, and 165, which may be made of silicide or n+ hydrogenated a-Si heavily doped with an N-type impurity, may be formed on the semiconductors 154.

A plurality of data lines 171 and a plurality of drain electrodes 175 may be formed on the ohmic contacts 161, 163, and 165, respectively, and on the gate insulating layer 140. The data lines 171 and the drain electrodes 175 are separated from the gate lines.

A gate electrode 124, a source electrode 173 connected with the gate line, a drain electrode 175, and a semiconductor 154 form a TFT having a channel formed in the semiconductor 154 disposed between the source electrode 173 and the drain electrode 175.

The ohmic contacts 161, 163, and 165 are only interposed between the underlying semiconductors 154 and the data lines 171 and the overlying drain electrodes 175, and reduce the contact resistance therebetween.

A passivation layer 180 may be formed on the data lines 171, the drain electrodes 175, and the exposed portions of the semiconductors 154.

The passivation layer 180 may be made of a photosensitive organic material having a good flatness characteristic, a low dielectric insulating material having a dielectric constant lower than 4.0, such as a-Si:C:O and a-Si:O:F formed by plasma enhanced chemical vapor deposition (PECVD), or an inorganic material, such as silicon nitride.

The passivation layer 180 has a plurality of contact holes 185 exposing the drain electrodes 175. A plurality of pixel electrodes 190, which are preferably made of ITO or IZO, are formed on the passivation layer 180. Alternatively, the pixel electrodes 190 may be made of a transparent conductive polymer or an opaque reflective metal when the LCD is a reflective type LCD.

A pixel electrode 190 and a common electrode 270 form a capacitor called a “liquid crystal capacitor,” which stores applied voltages after the TFT is turned off. An additional capacitor called a “storage capacitor,” may be connected in parallel with the liquid crystal capacitor to improve the voltage storing capacity.

The common electrode panel 200 is described below.

A light blocking member 220 that prevents light leakage may be formed on an insulating substrate 210, such as transparent glass. The light blocking member 220 may include a plurality of openings facing the pixel electrodes 190 and the light blocking member 200 may have substantially the same shape as the pixel electrodes 190. Alternately, the light blocking member may include portions corresponding to the data lines 171 and portions corresponding to the TFTs. A plurality of color filters 230 may be formed on the substrate 210 and may be disposed substantially in the areas enclosed by the light blocking member 220.

An overcoat 250 may be formed on the color filters 230. A common electrode 270, which may be made of a transparent conductive material such as ITO and IZO, may be formed on the overcoat 250.

Alignment layers 11 and 21 are formed on inner surfaces of the TFT array panel 100. The common electrode panel 200 thin film transistor and the polarizers 12 and 22 are attached on outer surfaces of the panels 100 and 200, respectively.

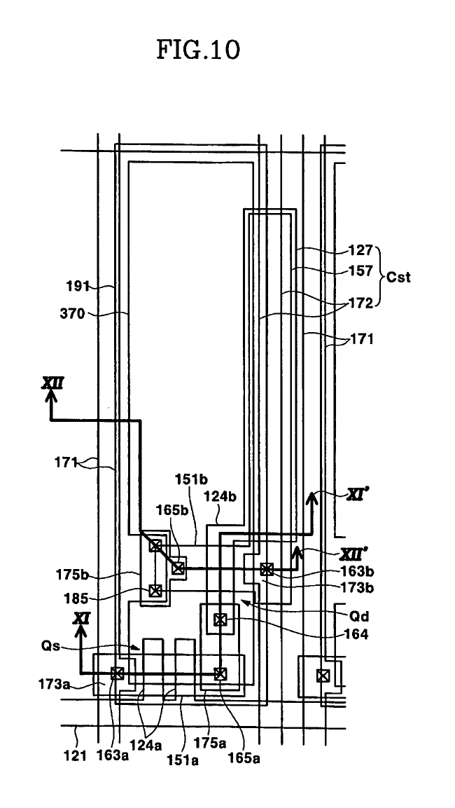

A TFT array panel for an OLED according to embodiments of the invention are described below with reference to FIGS. 10, 11, and 12.

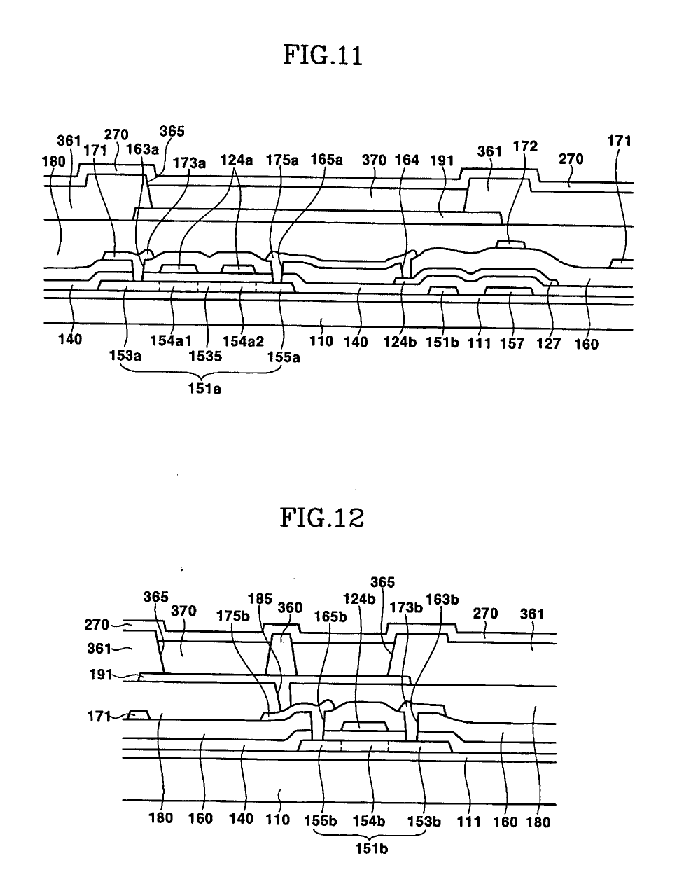

FIG. 10 is a layout view of a TFT array panel of an OLED according to an embodiment of the invention. FIG. 11 and FIG. 12 are sectional views of the TFT array panel shown in FIG. 10 taken along the line XII-XII′.

A blocking film 111, which may be made of silicon nitride (SiNx), or silicon oxide (SiOx) is formed on an insulating substrate 110, which may be made of transparent glass or plastic. The blocking film 111 may have a dual-layered structure or multi-layered structure.

A plurality of pairs of first and second semiconductor islands 151a and 151b, which may be made of polysilicon, are formed on the blocking film 111. Each of the semiconductor islands 151a and 151b includes a plurality of extrinsic regions having an N-type or P-type conductive impurity and at least one intrinsic region hardly including any conductive impurity.

Regarding the first semiconductor island 151a, the extrinsic regions include first source/drain regions 153a and 155a and an intermediate region 1535, which are doped with an N-type impurity and separated from one another. The intrinsic regions include a pair of first channel regions 154a1 and 154a2 disposed between the extrinsic regions 153a, 1535 and 155a.

Concerning the second semiconductor island 151b, the extrinsic regions include second source/drain regions 153b and 155b, which are doped with a P-type impurity and separated from one another. The intrinsic regions include a second channel region 154b disposed between the second source/drain regions 153b and 155b and a storage region 157 extending or projecting upward from the second source/drain region 153b.

The extrinsic regions may further include lightly doped regions (not shown) disposed between the channel regions 154a1, 154a2, and 154b and the source/drain regions 153a, 155a, 153b, and 155b. The lightly doped regions may be substituted with offset regions that contain substantially no impurity.

Alternatively, the extrinsic regions 153a and 155a of the first semiconductor islands 151a may be doped with a P-type impurity, while the extrinsic regions 153b and 155b of the second semiconductor islands 151b may be doped with an N-type impurity. The P-type impurity may be boron (B) gallium (Ga), or the like and the N-type impurity may be phosphorous (P), arsenic (As), or the like.

A gate insulating layer 140, which may be made of silicon nitride or silicon oxide, is formed on the semiconductor islands 151a and 151b and the blocking film 111.

A plurality of gate conductors that include a plurality of gate lines 121 having first control electrodes 124a and a plurality of second control electrodes 124b are formed on the gate insulating layer 140.

The gate lines 121 for transmitting gate signals extend in a substantially transverse direction. The first control electrodes 124a extend or project upward from the gate lines 121 and intersect the first semiconductor islands 151a such that the first electrodes 124a overlap with the first channel regions 154a1 and 154a2. Each gate line 121 may include an end portion having an area sufficient for contact with another layer or an external driving circuit. The gate lines 121 may connect with a gate driving circuit (not shown) for generating the gate signals. The gate driving circuit and the gate lines 121 may be integrated on the substrate 110.

The second control electrodes 124b are separated from the gate lines 121 and overlap with the second channel regions 154b. The second control electrodes 124b extend to form storage electrodes 127 overlapping with the storage regions 157 of the second semiconductor islands 151b.

The gate conductors 121 and 124b may be made of an Al-containing metal such as Al and an Al alloy (e.g. Al—Nd), an Ag-containing metal such as Ag and an Ag alloy, a Cu-containing metal such as Cu and a Cu alloy, a Mo-containing metal such as Mo and a Mo alloy, Cr, Ta, Ti, etc.

The gate conductors 121 and 124b may have a multi-layered structure including two films having different physical characteristics. One of the films may be made of a low resistivity metal including an Al-containing metal, an Ag-containing metal, and a Cu-containing metal for reducing signal delay or voltage drop. The other film may be made of a material such as a Mo-containing metal, Cr, Ta, or Ti, which has good physical, chemical, and electrical contact characteristics with other materials such as indium tin oxide (ITO) or indium zinc oxide (IZO). For example, the combination may be a lower Cr film and an upper Al (alloy) film and a lower Al (alloy) film and an upper Mo (alloy) film. However, the gate conductors 121 and 124b may be made of other metals or conductors. The lateral sides of the gate conductors 121 and 124b are inclined relative to a surface of the substrate 110, and the inclination angle thereof range approximately 30-80 degrees.

An interlayer insulating film 160 may be formed on the gate conductors 121 and 124b. The interlayer insulating film 160 may be made of an inorganic insulator such as silicon nitride and silicon oxide, an organic insulator, or a low dielectric insulator. The organic insulator or the low dielectric insulator preferably has a dielectric constant less than about 4.0, and includes a-Si:C:O and a-Si:O:F formed by plasma enhanced chemical vapor deposition (PECVD). The organic insulator for the interlayer insulation 160 may have photosensitivity, and the interlayer insulation 160 may have a flat or planar surface.

The interlayer insulating film 160 has a plurality of contact holes 164 exposing the second control electrodes 124b. In addition, the interlayer insulating film 160 and the gate insulating layer 140 have a plurality of contact holes 163a, 163b, 165a and 165b exposing the source/drain regions 153a, 153b, 155a, and 155b, respectively.

A plurality of data conductors including a plurality of data lines 171, a plurality of driving voltage lines 172, and a plurality of first and second output electrodes 175a and 175b are formed on the interlayer insulating film 160.

The data lines 171 for transmitting data signals extend in a substantially longitudinal direction and intersect with the gate lines 121. Each data line 171 includes a plurality of first input electrodes 173a connected with the first source/drain regions 153a through the contact holes 163a. Each data line 171 may include an end portion having an area sufficient for contact with another layer or an external driving circuit. The data lines 171 may connect with a data driving circuit (not shown) to generate the data signals, which may be integrated on the substrate 110.

The driving voltage lines 172 for transmitting driving voltages extend substantially in the longitudinal direction and intersect with the gate lines 121. Each driving voltage line 172 includes a plurality of second input electrodes 173b connected with the second source/drain regions 153b through the contact holes 163b. The driving voltage lines 171 overlap with the storage electrodes, 127 and the driving voltage lines 171 may be connected with each other.

The first output electrodes 175a are separated from the data lines 171 and the driving voltage lines 172 and are connected with the first source/drain regions 155a through the contact holes 165a and with the second control electrodes 124b through the contact hole 164.

The second output electrodes 175b are separated from the data lines 171, the driving voltage lines 172, and the first output electrodes 175a and are connected with the second source/drain regions 155b through the contact holes 165b.

The data conductors 171, 172, 175a, and 175b may be made of a refractory metal such as Mo, Cr, Ti, Ta, or an alloy thereof. The data conductors 171, 172, 175a, 176b may have a multi-layered structure, which may include a refractory metal film and a low resistivity film. For example, the multi-layered structure may be a double-layered structure that includes a lower Cr film and an upper Al (alloy) film, a double-layered structure of a lower Mo (alloy) film and an upper Al (alloy) film. The multi-layered structure may be a triple-layered structure of a lower Mo (alloy) film, an intermediate Al (alloy) film, and an upper Mo (alloy) film.

Similar to the gate conductors 121 and 124b, the data conductors 171, 172, 175a, and 175b have inclined edge profiles and the inclination angles thereof are approximately 30-80 degrees.

A passivation layer 180 may be formed on the data conductors 171, 172, 175a, and 175b. The passivation layer 180 may be approximately 1.0-10.0 microns thick and the passivation layer 180 may be made of an organic insulator such as polyimide or poly-acryl that are capable of providing a flat surface. It is understood that the passivation layer 180 may be made of inorganic insulator, another organic insulator, or a low dielectric insulator.

The passivation layer 180 has a plurality of contact holes 185 exposing the second output electrodes 175b. The passivation layer 180 may further have a plurality of contact holes (not shown) exposing end portions of the data lines 171 and the passivation layer 180 and the interlayer insulating film 160 may have a plurality of contact holes (not shown) exposing end portions of the gate lines 121.

A plurality of pixel electrodes 191 may be sequentially formed on the passivation layer 180. The pixel electrodes 191 are connected with the second output electrodes 175b through the contact holes 185.

The pixel electrodes 191 may be made of a reflective conductor such as Cr, Al, Ag, or alloys thereof having a reflectance greater than approximately 70% for visible light. The pixel electrodes 191 may be approximately 10 nm to 500 nm thick.

A plurality of auxiliary electrodes (not shown), which may be made of a material such as ITO or IZO having a higher work function (e.g., higher than about 5 eV) than the pixel electrodes 191, may be formed on the pixel electrodes 191 to enhance the injection of the electrons.

A plurality of contact assistants (not shown) or connecting members (not shown) may be formed on the passivation layer 180 such that they are connected with the exposed end portions of the gate lines 121 or the data lines 171.

A partition 361 may be formed on the passivation layer 180. The partition 361 surrounds the pixel electrodes 191 to define openings 365 and may be made of an organic or inorganic insulating material. The partition 361 may be made of a photosensitive material having a black pigment such that the partition 361 functions as a light blocking member, and the formation of the partition 361 may be simplified.

A plurality of light emitting members 370 may be formed on the pixel electrodes 191 and provided in the openings 365 defined by the partition 361. Each of the light emitting members 370 may be made of an organic material that emits a color, such as one of primary color lights of red, green, and blue light. The OLED display displays images by spatially adding the monochromatic primary color lights emitted from the light emitting members 370.

Each of the light emitting members 370 may have a multilayered structure including an emitting layer (not shown) for emitting light and auxiliary layers (not shown) for improving the efficiency of light emission of the emitting layer. The auxiliary layers may include an electron transport layer (not shown) and a hole transport layer (not shown) for improving the balance of the electrons and holes, and an electron injecting layer (not shown) and a hole injecting layer (not shown) for improving the injection of the electrons and holes.

A common electrode 270 is formed on the light emitting members and the partition 361. The common electrode 270 is supplied with the common voltage and may be made of a transparent material such as ITO and IZO.

In the above-described OLED display, a first semiconductor island 151a, a first control electrode 124a connected with a gate line 121, a first input electrode 153a connected with a data line 171, and a first output electrode 155a form a switching TFT Qs having a channel formed in the channel regions 154a1 and 154a2 of the first semiconductor 151a. Similarly, a second semiconductor island 151b, a second control electrode 124b connected with a first output electrode 155a, a second input electrode 153b connected with a driving voltage line 172, and a second output electrode 155b connected to a pixel electrode 191 form a driving TFT Qd having a channel formed in the second channel region 154b of the second semiconductor island 151b. A pixel electrode 191, a light emitting member 370, and the common electrode 270 form an organic light emitting diode having the pixel electrode 191 as an anode and the common electrode 270 as a cathode or vice versa. The overlapping portions of a storage electrode 127, a driving voltage line 172, and a storage region 157 form a storage capacitor Cst.

The switching TFT Qs transmits data signals from the data line 171 in response to a gate signal from the gate line 121. The driving TFT Qd drives a current having a magnitude depending on the voltage difference between the second control electrode 124b and the second output electrode 175b upon receipt of the data signals. The voltage difference between the second control electrode 124b and the second input electrode 173b is stored in the storage capacitor Cst and maintained after the switching TFT Qs turns off. The light emitting diode emits light having an intensity depending on the current driven by the driving TFT Qd. The monochromatic primary color lights emitted from the light emitting diodes are spatially added to display images.

The OLED display according to the above-described embodiment of the invention, which includes the opaque pixel electrodes 191 and the transparent common electrode 270, emits light toward the top of the substrate 110 and is referred to as a top emission OLED display. The present invention may also be employed to a bottom emission OLED display that includes transparent pixel electrodes 191 and an opaque common electrode 270 and emits light toward the bottom of the substrate 110.

The semiconductor islands 151a and 151b may be made of amorphous silicon without an intrinsic region. Ohmic contacts (not shown), which may be made of amorphous silicon heavily doped with an N-type impurity may be provided between the semiconductor islands 151a and 151b and the data conductors 171, 172, 175a, and 175b.

The first and second control electrodes 124a and 124b may be provided under the semiconductor islands 151a and 151b, respectively, while the gate insulating layer 140 is provided between the semiconductor islands 151a and 151b and the first and second control electrodes 124a and 124b. The data conductors 171, 172, 173b, and 175b may be provided directly on the gate insulating layer 140.

In addition, the data conductors 171, 172, 173b and 175b may be provided beneath the semiconductor islands 151a and 151b and may be electrically coupled with the semiconductor islands 151a and 151b.

According to at least the above described embodiments of the invention, by correcting the misalignment of the deposited ink position, the ink is precisely deposited into corresponding pixels, and thereby the ink spreading between adjacent color filters decreases and the image quality of the display devices improves.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents

What is claimed is:

1. A panel for a display device, comprising:
a substrate;
a sidewall member provided on the substrate and having a plurality of openings;
a plurality of color filters provided in the openings; and
at least one inspection pattern for inspecting a misalignment of the color filters.

2. The panel of claim 2, wherein the inspection pattern is provided on an edge portion of the sidewall member or an edge portion of the substrate.

3. The panel of claim 1, wherein the sidewall member is a light blocking member.

4. The panel of claim 1, wherein a center of the inspection pattern is positioned along a same line as a center of each of the color filters that are arranged along the same row.

5. The panel of claim 1, wherein the inspection pattern is substantially circular and comprises a plurality of alignment lines having a plurality of divisions.

6. The panel of claim 1, wherein the alignment lines intersect each other.

7. The panel of claim 1, wherein the inspection pattern is larger than a drop of ink.

8. The panel of claim 1, wherein each color filter represents one of a red color, a green color, or a blue color.

9. The panel of claim 8, wherein there is at least one inspection pattern arranged for each color filter row having the same color.

10. The panel of claim 1, wherein the panel is a liquid crystal display panel.

11. The panel of claim 10, further comprising:
a plurality of signal lines;
a plurality of transistors coupled with the signal lines; and
a plurality of pixel electrodes electrically coupled with the signal lines through the transistors.

12. A method of manufacturing a panel for a display device, comprising:
depositing ink into an inspection pattern;
inspecting a position of the deposited ink in the inspection pattern;
adjusting a position of a substrate or a head of an inkjet printing device to align a center of the deposited ink with a center of the inspection pattern; and
depositing ink into an opening.

13. The method of claim 12, wherein the ink is one of a red color, a green color, and a blue color.

14. The method of claim 12, wherein the sidewall member is a light blocking member.

15. The method of claim 12, wherein the panel is a liquid crystal display panel or an organic electroluminescence display panel.

16. The method of claim 12, wherein the panel comprises:
a plurality of signal lines;
a plurality of transistors coupled with the signal lines; and
a plurality of pixel electrodes electrically coupled with the signal lines through the transistors.

17. A panel for a display device, comprising:
a substrate;
a sidewall member provided on the substrate and including a plurality of openings;
a plurality of organic light emitters provided in the openings and representing a color, respectively; and
an inspection pattern for inspecting a misalignment of the organic light emitters.

18. The panel of claim 17, wherein the inspection pattern is provided on an edge portion of the sidewall member or an edge portion of the substrate.

19. The panel of claim 17, wherein a center of the inspection pattern is positioned along a same line as a center of each of the organic light emitters that are arranged along the same row.

20. The panel of claim 17, wherein the inspection pattern is substantially circular, and comprises a plurality of alignment lines having a plurality of divisions.

21. The panel of claim 17, wherein the alignment lines intersect each other.

22. The panel of claim 17, wherein the inspection pattern is larger than a drop of ink.

23. The panel of claim 17, wherein each organic light emitter represents one of a red color, a green color, or a blue color.

24. The panel of claim 17, wherein there is at least one inspection pattern arranged for each organic light emitter row having the same color.

25. The panel of claim 17, wherein the panel is an organic electroluminescence display panel.

26. The panel of claim 25, further comprising:
a plurality of signal lines;
a plurality of transistors coupled with the signal lines; and
a plurality of pixel electrodes electrically coupled with the signal lines through the transistors.
